(19) United States
(12) Patent Application Publication
(10) Pub. No.: US 2026/0005180 A1
(43) Pub. Date: Jan. 1, 2026

(54) LAND-SIDE DIE COOLING OF DOUBLE-SIDED PACKAGE SUBSTRATES

(71) Applicant: Intel Corporation, Santa Clara, CA (US)

(72) Inventors: Tarek GEBRAEL, Chandler, AZ (US); Mohamed ELHEBEARY, Chandler, AZ (US); Darshan RAVOORI, Chandler, AZ (US); Matthew T. MAGNAVITA, Chandler, AZ (US); Xiao LU, Chandler, AZ (US)

(21) Appl. No.: 18/758,138

(22) Filed: Jun. 28, 2024

(51) Int. Cl. H01L 23/00; H01L 23/36; H01L 23/498; H01L 23/538; H01L 25/10

(52) U.S. Cl. CPC H01L 24/29; H01L 23/3675; H01L 23/3737; H01L 23/49816; H01L 24/27; H01L 24/32; H01L 24/83; H01L 25/03; H01L 25/0655; H05K 1/181; H01L 2224/27001; H01L 2224/2781; H01L 2224/29109; H01L 2224/29111; H01L 2224/29113; H01L 2224/29116; H01L 2224/29139; H01L 2224/29147; H01L 2224/32225; H01L 2224/83012; H01L 2224/83024; H01L 2224/83035; H05K 1/021

(57) ABSTRACT

Semiconductor device assemblies that comprise a package substrate having semiconductor devices on two sides. A solder layer can thermally couple one or more semiconductor devices on a side of the package with a circuit board. Methods of manufacturing assemblies having a semiconductor device thermally coupled to a circuit board are also provided.

### FIELD

Descriptions are generally related to semiconductor device assemblies, and more particular descriptions are related to heat management for semiconductor device packages that include land-side devices on package substrates.

### BACKGROUND

Semiconductor chips are central to intelligent devices and systems, such as personal computers, laptops, tablets, phones, servers, and other consumer and industrial products and systems. Manufacturing semiconductor chips presents a number of challenges and these challenges are amplified as devices become smaller and performance demands increase. Challenges include, for example, unwanted material interactions, precision and scaling requirements, power delivery requirements, limited failure tolerance, and material and manufacturing costs.

The increasing demand for higher computing power and efficiency necessitates new packaging architectures. One approach to increase a system's performance is to increase its volumetric density by adding silicon devices in unused regions of a semiconductor device packaging assembly. For example, the land-side of a semiconductor device package substrate is an area where additional silicon devices can be added. Examples of silicon devices include chiplets, which can be processors broken up into more than one chip and that can provide additional computing power in a package assembly, and voltage regulators (VR).

### BRIEF DESCRIPTION OF THE DRAWINGS

The figures are provided to aid in understanding the disclosure. The figures can include diagrams and illustrations of examples of structures, assemblies, data, methods, and systems. For ease of explanation and understanding, these structures, assemblies, data, methods, and systems, the figures are not an exhaustively detailed description. The figures therefore should not be understood to depict the entire bounds of structures, assemblies, data, methods, and systems possible without departing from the scope of the disclosure.

Additionally, features are not necessarily illustrated relatively to scale due in part to the small sizes of some features and the desire for clarity of explanation in the figures.

FIGS. 1A-1C illustrate semiconductor device assemblies that include a thermal management layer between a land-side semiconductor device and a circuit board.

FIGS. 2A-2B show a method for manufacturing a semiconductor device assembly that includes a thermal management layer between a land-side semiconductor device and a circuit board.

FIG. 3 provides a method for manufacturing a semiconductor device assembly that includes a thermal management layer between a land-side semiconductor device and a circuit board.

FIG. 4 provides an example of a computing system.

Descriptions of certain details and implementations follow, including non-limiting descriptions of the figures, which depict some examples and implementations.

### DETAILED DESCRIPTION

References to one or more examples are to be understood as describing a particular feature, structure, or characteristic included in at least one implementation. The phrases “one example” or “an example” are not necessarily all referring to the same example or embodiment. Any aspect described herein can potentially be combined with any other aspect or similar aspect described herein, regardless of whether the aspects are described with respect to the same figure or element.

The words “connected” and/or “coupled” can indicate that two or more elements are in direct physical or electrical contact with each other. The term “coupled,” however, can also mean that two or more elements are not in direct contact with each other and are instead separated by one or more elements but they may still co-operate or interact with each other, for example, physically, magnetically, optically, or electrically.

The words “first,” “second,” and the like, do not indicate order, quantity, or importance, but rather are used to distinguish one element from another. The words “a” and “an” herein do not indicate a limitation of quantity, but rather denote the presence of at least one of the referenced items. The terms “follow” or “after” can indicate immediately following or following some other event or events. Other sequences of operations can also be performed according to alternative embodiments. Furthermore, additional operations may be added or removed depending on the application.

Disjunctive language such as the phrase “at least one of X, Y, or Z,” is used in general to indicate that an element or feature, may be either X, Y, or Z, or any combination thereof (e.g., X, Y, and/or Z). Thus, this disjunctive language should be understood not to imply that certain embodiments require at least one of X, at least one of Y, or at least one of Z to each be present.

Flow diagrams as illustrated herein provide examples of sequences of various process actions. The flow diagrams can indicate operations to be executed by a software or firmware routine and/or physical operations. Physical operations can be performed by semiconductor processing equipment, including pick and place systems, and solder dispensing systems. Although shown in a particular sequence or order, unless otherwise specified, the order of the actions can be modified. Thus, the illustrated diagrams should be understood as examples. The processes can be performed in a different order, and some actions can be performed in parallel. Additionally, one or more actions can be omitted and not all implementations may necessarily perform all actions.

Various components described can be a means for performing the operations or functions described. Components described can include software, hardware, or a combination of these. Some components can be implemented as software modules, hardware modules, special-purpose hardware (for example, application specific hardware, application specific integrated circuits (ASICs), and digital signal processors (DSPs)), embedded controllers, and/or hardwired circuitry. Other components can be semiconductor processing equipment that is able to perform physical operations such as, for example, pick-and-place operations, solder ball dispensing, lithography, material deposition (for example, chemical vapor deposition, atomic layer deposition, physical vapor deposition, electrodeposition, and/or sputtering), chemical mechanical polishing, surface cleaning, and etching.

To the extent various computer operations or functions are described herein, they can be described or defined as software code, instructions, configuration, and/or data. The software content can be provided via an article of manufacture with the content stored thereon, or via a method of operating a communication interface to send data via the communication interface. A machine-readable storage medium can cause a machine to perform the functions or operations described. A machine-readable storage medium includes any mechanism that stores information in a tangible form accessible by a machine (e.g., computing device), such as recordable/non-recordable media (e.g., read only memory (ROM), random access memory (RAM), magnetic disk storage media, optical storage media, flash memory devices). Instructions can be stored on the machine-readable storage medium in a non-transitory form. A communication interface includes any mechanism that interfaces to, for example, a hardwired, wireless, or optical medium to communicate to another device, such as, for example, a memory bus interface, a processor bus interface, an Internet connection, a disk controller.

Terms such as chip, die, IC (integrated circuit) chip, IC die, microelectronic chip, microelectronic die, semiconductor die, semiconductor device, and/or semiconductor chip are interchangeable and refer to a device comprising integrated circuits that can be formed in part from semiconductor materials.

Semiconductor chip manufacturing processes are sometimes divided into front end of the line (FEOL) processes and back end of the line (BEOL) processes. Electronic circuits and active and passive devices within the chip, such as for example, transistors, capacitors, resistors, and/or memory cells, are manufactured in what can be referred to as FEOL processes. Memory cells include, for example, electronic circuits for random access memory (RAM), such as static RAM (sRAM), dynamic RAM (DRAM), read only memory (ROM), non-volatile memory, and/or flash memory. FEOL processes can be, for example, complementary metal-oxide semiconductor (CMOS) processes. BEOL processes include metallization of the chip where interconnects are formed in layers and the feature size of the interconnect increases in layers nearer the surface of the semiconductor chip. Interconnects in, for example, semiconductor chips that are integrated into heterogeneous packages (such as, for example, packages that include memory and logic chips), can also include through silicon vias (TSVs) that transverse the semiconductor chip device region. Semiconductor devices that have TSVs can blur distinctions between BEOL and FEOL processes.

Semiconductor chip interconnects can be created by forming a trench or though-layer via by etching a trench or via structure into a dielectric layer and filling the trench or via with metal. Dielectric layers can comprise, for example, low-κ dielectrics, SiO₂, silicon nitride (SiN), silicon carbide (SiC), and/or silicon carbonitride (SiCN). Low-κ dielectrics include for example, fluorine-doped SiO₂, carbon-doped SiO₂, porous SiO₂, porous carbon-doped SiO₂, combinations for the foregoing, and also these materials with gas-filled gaps or bubbles. Dielectric layers that include conductive features can be interlayer dielectric (ILD) features. In general, low-κ dielectrics exhibit a dielectric constant that is less than that of SiO₂.

The terms “package,” “packaging,” “IC package,” or “chip package,” “microelectronics package,” or “semiconductor chip package” are interchangeable and generally refer to an enclosed carrier of one or more semiconductor chips, in which the semiconductor chips are coupled to a package substrate and encapsulated. The package substrate provides electrical interconnections between the chip(s) and other chips and/or a motherboard or other circuit board for I/O (input/output) communication and power delivery. A package with multiple chips can, for example, be a system in a package.

A package substrate generally includes dielectric layers or structures having conductive structures on, through, and/or embedded in the dielectric layers. The dielectric layers can be, for example, build-up layers. Dielectric materials include Ajinomoto build-up film (ABF), although other dielectric materials are possible. Semiconductor package substrates can have cores or be coreless. Semiconductor packages having cores can have dielectric layers such as buildup layers on more than one side of a core, such as on two opposite sides of a core. Cores can include through-core vias that contain a conductive material. Other structures or devices are also possible within a package substrate.

A “core” or “package core” generally refers to a layer usually embedded within a package substrate. The core can provide structure or stiffness to a package substrate. A core is an optional feature of a package substrate. The core can be a dielectric organic or inorganic material and may have conductive vias extending through the layer. The conductive vias can include a metal, for example, copper. A package core can, for example, be comprised of a glass material (such as, for example, aluminosilicate, borosilicate, alumino-borosilicate, silica, and fused silica), silicon, silicon nitride, silicon carbide, gallium nitride, or aluminum oxide. In some examples, core materials are glass-fiber reinforced organic resins such as epoxy-based resins. A further example package substrate core is FR4 (woven glass fiber reinforces epoxy). In other examples, package substrate cores are solid amorphous glass materials.

In further examples of a package substrate core, the substrate core is a glass core comprising a solid amorphous glass material. The glass substrate core can comprise a glass such as, for example, aluminosilicate, borosilicate, alumino-borosilicate, silica, and fused silica, that additionally optionally comprises one or more of the following: Al₂O₃, B₂O₃, MgO, CaO, SrO, BaO, SnO₂, Na₂O, K₂O, SrO, P₂O₃, ZrO₂, Li₂O, Ti, and/or Zn. In further examples of glass cores, the glass can comprise silicon and oxygen, as well as optionally any one or more of: aluminum, boron, magnesium, calcium, barium, tin, sodium, potassium, strontium, phosphorus, zirconium, lithium, titanium, and/or zinc. In some examples, a glass package substrate core comprises at least 23% silicon, at least 26% oxygen by weight. In further examples, the glass package substrate core comprises at least 23% silicon, at least 26% oxygen, and at least 5% aluminum by weight.

Additionally, examples of solid amorphous glass substrate cores can be considered to have a rectangular prism volume. The rectangular prism volume can contain vias that have been filled with one or more different materials. A material in a via can be a conductive metal such as copper. Examples of solid amorphous glass substrate cores can have a thickness in the range of 50 μm to 1.4 mm. Additionally, the package substrate can include a multi-layer glass substrate. The package substrate in this example may be a coreless substrate. The multi-layer glass substrate can have a thickness, for example, in the range of 25 μm to 50 μm. Further, glass substrate cores can have dimensions on a side of 10 mm to 250 mm. For example, the substrate core can be 10 mm by 10 mm up to 250 mm by 250 mm in two dimensions, but substrate cores do not necessarily have to have the same value in both dimensions.

A package substrate can include one or more interconnect bridges. The interconnect bridge can be partially, fully, or not embedded into the package substrate. An interconnect bridge provides interconnects between chips that are housed on the package substrate. The interconnects can provide signal I/O between the chips. Some interconnect bridges, such as ones that have conductive through-bridge vias, can also provide power to an operably connected chip. The interconnect bridge can include regions having traces that have a smaller width dimension (the smallest dimension of the trace), a smaller height dimension, and/or a length dimension than the vias and traces of the surrounding package substrate. For example, width dimensions (or smallest dimension) can be 3 μm or less and/or 10 μm or less in some regions. The interconnect bridges can also have smaller trace spacings than the surrounding package substrate. For example, trace center-to-center spacings can be 3 μm and/or less or 10 μm or less in some regions. The interconnect bridge substrate can comprise, for example, silicon, silicon-on-insulator, float glass, borosilicate glass, silicon dioxide, polymeric, one or more organic polymeric materials, ceramic, and/or a silicon nitride material. The interconnect bridge substrate can comprise, for example, one or more dielectric layers that are comprise of, silicon oxides, silicon nitride, silicon oxynitride, carbon-doped oxide, methyl silsesquioxane, hydrogen silsesquioxane, die backside film (DBF), an epoxy film, a B-stage epoxy film, other dielectric material. The interconnect bridge can also include a coreless substrate comprised of a plurality of dielectric layers. The dielectric layers can be, for example, die backside film (DBF), an epoxy film, a B-stage epoxy film, or other dielectric material. Other materials are also possible for interconnect bridge substrates. Other materials are possible.

For packages that include interconnect bridges, the pitch in the interconnect bridge region for first level interconnects (FLIs) assemblies can be less than the pitch for other regions of the FLI assembly. The pitch in the interconnect bridge region for FLIs can be, for example, less than or equal to 25 μm.

Incorporating through-bridge vias (TBVs) into interconnect bridges can enable power to be routed from a substrate package cavity to a semiconductor device attached to a package substrate. Through-bridge-vias can reduce the number of substrate routing layers required in a package substrate and can result in improved packaging yields. An interconnect bridge having TBVs can be for example, EMIB with TBVs, or EMIB-T. Depending on the bridge substrate material, a TBV may also be described as a through-silicon via (TSV) if the via traverses a region comprised of silicon, for example.

Attaching semiconductor devices on the land-side of package substrates can create thermal management difficulties. The gap height between the substrate and motherboard can be on the order of hundreds of microns, which can make it challenging to incorporate a device cooling solution. Cooling solutions need to also be compatible with current package assembly processes. For example, some assembly processes require strict keep-out zones that can limit the types of materials that can be selected in surface mount technology (SMT) processes.

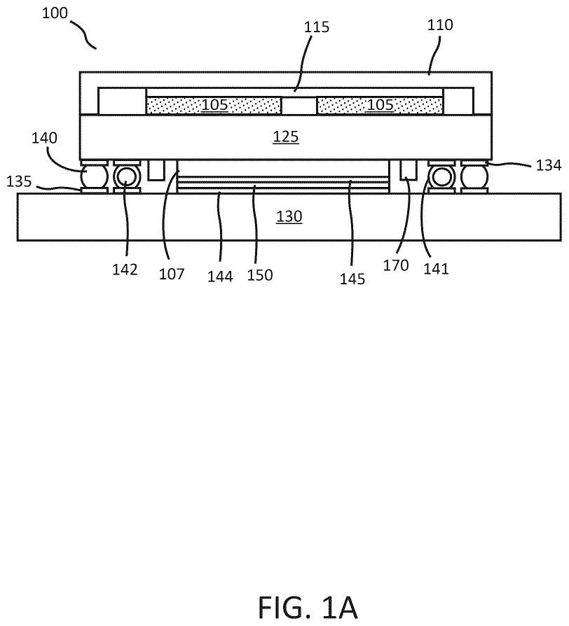

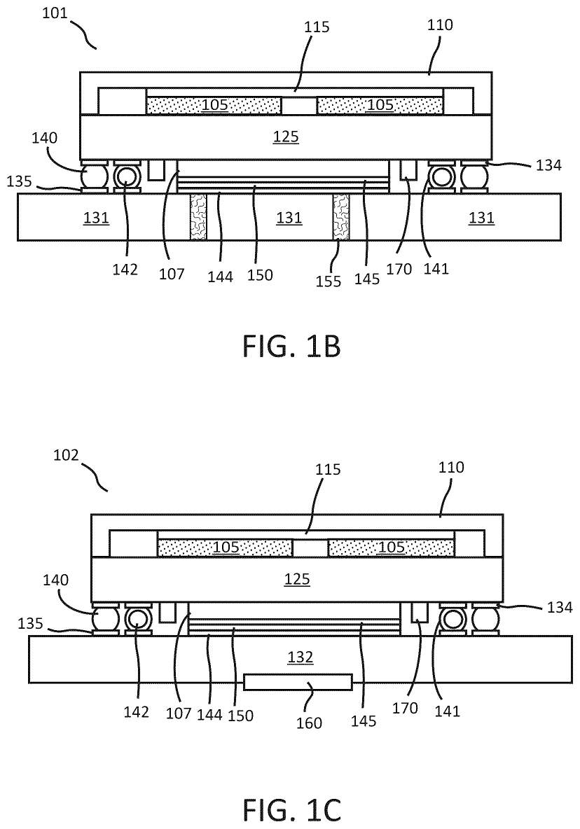

FIGS. 1A-1C provide semiconductor device assemblies 100, 101, and 102, respectively, comprising semiconductor devices 105 and 107 on two opposing sides of a package substrate 125. Semiconductor devices 105 and 107 are electrically coupled to package substrate 125 through an interconnect region (not shown). Although two semiconductor devices 105 and one semiconductor device 107 are shown, other numbers of semiconductor devices 105 and 107 are possible, such as one, three, or more semiconductor devices 105 and two, three, or more semiconductor devices 107. Semiconductor device assemblies 100, 101, and 102 additionally comprise a heat spreader 110, a thermal interface material (TIM) 115, and package substrate 125. Heat spreaders 110 can be, for example, a metallic plate comprised of, for example, a thermally conductive material, such as, copper, gold, palladium, aluminum, or a combination thereof. Thermal interface materials 115 can be materials that aid in thermally coupling the heat spreader 110 with the semiconductor devices 105. Heat spreaders 110 can be, for example, integrated heat spreaders (IHSs). Typically, TIMs 115 are deformable and thermally conductive materials, and a variety of materials are possible, such as, for example, pastes, gels, greases, epoxies, silicone-based materials, and adhesives. TIMS can comprise, metallic particles. Other materials are possible for TIMs 115. Package substrate 125 can be any of the types of package substrates described herein. Semiconductor devices 105 and 107 can be electrically coupled to package substrate 125 through electrically conductive members (not shown), for example, pins, rods, pads, and/or solder regions that can be comprised of one or more metals, such as, for example, copper, gold, silver, antimony, lead, and/or aluminum.

Package substrate 125 is electrically coupled to a circuit board 130, 131, or 132 (FIG. 1A, 1B, or 1C, respectively) through conductive pads 134 and 135 and solder join regions 140 and 141. Solder join regions 140 and 141 can be in the form of balls or other shapes. Circuit boards 130, 131, and 132 can be, for example, a mother board, a logic board, a mainboard, a system board, and/or a printed circuit board. Conductive pads 134 and 135 can be comprised of one or more metals, such as for example, copper, gold, and/or silver, although other conductive materials are possible. Solder join regions 141 can optionally comprise a core member 142 that is less deformable than the surrounding solder 141. The core member 142 can be non-collapsible under typical semiconductor package assembly conditions. Core member 142 can be comprised of, for example, copper, gold, nickel, palladium, and/or silver, or an alloy thereof, although other conductive materials are also possible. Core member 142 can comprise a copper core having a nickel coating or a solder material having a higher melting temperature than surrounding solder 141. Additionally core member 142 can comprise an elastomer material having metal layers on the surface, such as a copper layer and/or a nickel layer. The elastomer material can be non-collapsible under typical semiconductor package assembly conditions. Core member 142 can aid in maintaining a desired gap height between the package substrate 125 and the circuit board 130.

Semiconductor device 107 is thermally coupled to a circuit board 130, 131, or 132 through a solder region 150. The solder region 150 can be thermally coupled to a metallic pad 144 (of a circuit board 130, 131, or 132) and a backside metal region 145 of semiconductor device 107. The solder region 150 can generally be comprised of a solder material that is capable of conducting heat. Some example solder materials include materials comprised of tin, indium, gallium, gold, lead, copper, silver, bismuth, and/or antimony. Example solders include, mixtures of tin and bismuth (which can be low temperature (LT) solders), mixtures of tin, silver, and copper (e.g., Sn—Ag—Cu or SAC solders), mixtures of indium and bismuth, mixtures of indium and tin, and mixtures of indium, tin, and bismuth. Other compositions for solder materials are possible. The solder region 150 can have a thickness that is, for example, between 10 μm and 1000 μm thick, although other thicknesses are possible. The solder region 150 can cover more than 50%, more than 75%, more than 80%, more than 85%, more than 90%, more than 95%, or more than 98% of a surface of the semiconductor device 107. The solder region 150 can cover, for example, 50% to 100% of a surface of the semiconductor device 107. Semiconductor device backside metal region 145 can be comprised of one or more layers and/or alloys of, for example, titanium, vanadium, nickel, gold, copper, platinum, and/or palladium. An example backside metal region 145 is comprised of titanium, aluminum, silver nickel, and gold. Metallic pad 144 that is associated with circuit board 130 can be comprised of, for example, layers and/or alloys of, for example, solder materials, titanium, vanadium, nickel, gold, copper, platinum, and/or palladium. Other materials are also possible. Semiconductor device assemblies 100, 101, and 102 can also include optional land-side capacitors 170 and/or other devices coupled to the land-side of the package substrate 125. Although two land-side capacitors 170 are shown, other numbers and locations are possible for land-side capacitors 170.

In FIG. 1B, the circuit board 131 includes thermal vias 155. Thermal vias 155 can be comprised of a material that is capable of transferring heat to a greater amount than the surrounding circuit board 131. The material in thermal vias 155 can be a metal such as copper, aluminum, an alloy of copper and/or aluminum, or another metal or alloy. Although two thermal vias 155 are shown, other numbers are possible, such as one, three, or more. Additionally, other positions relative to semiconductor chip 107 are possible for thermal vias 155. In FIG. 1C, the circuit board 132 includes a heat sink 160. Heat sink 160 can be fully embedded in, partially embedded in, or on a surface of the circuit board 132. Heat sink 160 can be comprised of a material that is capable of transferring heat to a greater amount than the surrounding circuit board 132. Heat sink 160 can be comprised a metal such as copper, aluminum, gold an alloy of copper, gold, and/or aluminum, or another metal or alloy, or one or more layers of these materials on a block of one of these materials. Other shapes, locations and sizes relative to semiconductor device 107 are also possible for heat sink 160. Additionally, a circuit board 132 can include thermal vias, such as thermal vias 155 in addition to heat sink 160.

Although in FIGS. 1A-1C, one package substrate 125 and one circuit board 130, 131, or 132 are depicted, it is possible to also create a stack comprising more than two levels where package substrates include land-side semiconductor devices 107. The land-side semiconductor devices 107 and solder domes 225 can be placed between any two levels of a stacked assembly comprising more than two levels.

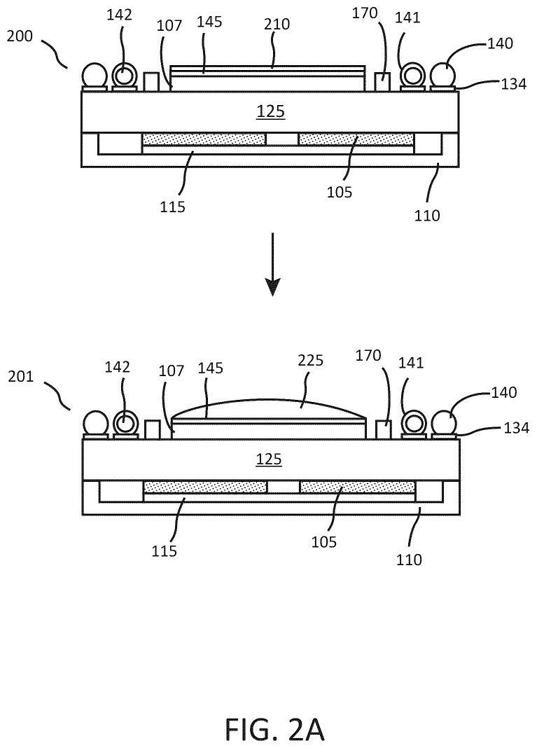

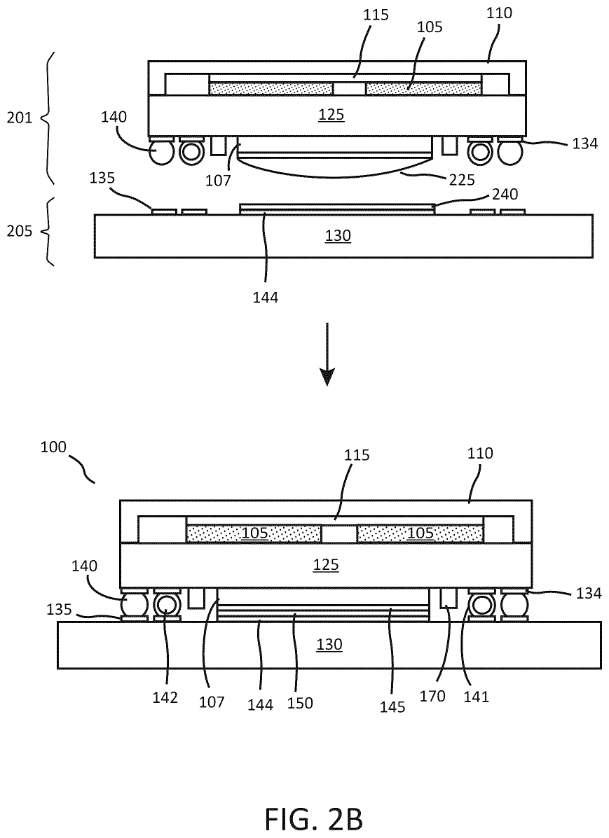

FIGS. 2A-2B describe a method for manufacturing an assembly comprising semiconductor devices on opposite sides of a package substrate. In FIGS. 2A-2B, some parts are numbered similarly to parts in FIGS. 1A-1C, and descriptions for similarly numbered parts found herein for parts in FIGS. 1A-1C are applicable to the same-numbered parts in FIGS. 2A-2B. In FIG. 2A-2B, a package substrate 125 has semiconductor devices 105 and 107 electrically coupled to two opposite sides. Different numbers of semiconductor devices 105 and 107 are also possible. A flux material (or solder paste) is sprayed or dispensed onto a surface of semiconductor device 107 comprising backside metallization region 145, creating flux layer 210 (or solder paste layer 210). Flux layer 210 (or solder paste layer 210) is illustrated on partially manufactured semiconductor device assembly 200 of FIG. 2A. A flux layer 210 can remove any native oxides and aid in dispensing solder onto the surface of backside metallization region 145 by increasing the adhesion between the solder material and the backside metallization region 145. The solder material can generally be comprised of a solder material that is capable of conducting heat. Some example solder materials include materials comprised of tin, indium, gallium, gold, lead, copper, silver, bismuth, and/or antimony. Example solders include, mixtures of tin and bismuth (which can be low temperature (LT) solders), mixtures of tin, silver, and copper (e.g., Sn—Ag—Cu or SAC solders), mixtures of indium and bismuth, mixtures of indium and tin, and mixtures of indium, tin, and bismuth. Other compositions for solder materials are possible. Solder material in the form of solder preforms or solder paste can be placed on the flux layer 210 and can be reflowed in a mass reflow oven and the flux residue layer removed, creating partially manufactured semiconductor device assembly 201. The molten solder can form a layer of solder (solder dome 225) covered with a layer of transparent flux residue. The flux residue layer can be removed through a deflux process. The deflux process can be a cleaning process that uses pressured water followed by air drying. Partially manufactured semiconductor device assembly 201 includes a solder dome 225. The solder dome 225 can cover more than 50%, more than 75%, more than 80%, more than 85%, more than 90%, more than 95%, or more than 98% of a surface of the semiconductor device 107. The solder region 150 can cover, for example, 50% to 100% of a surface of the semiconductor device 107.

In FIG. 2B, partially manufactured semiconductor device assembly 201 is mated to circuit board assembly 205 through a SMT process to create semiconductor device assembly 100. Optionally, some solder join regions 141 can include a core member 142. The core member 142 is less deformable than the surrounding solder region 141. Core member 142 can be comprised of, for example, copper, gold, nickel, palladium, and/or silver, or an alloy thereof, although other conductive materials are also possible. Core member 142 can comprise a copper core having a nickel coating or a solder material having a higher melting temperature than surrounding solder 141. Additionally core member 142 can comprise an elastomer material having metal layers on the surface, such as a copper layer and/or a nickel layer. The elastomer material can be non-collapsible under package assembly conditions. Core member 142 can aid in maintaining a desired gap height between the package substrate 125 and the circuit board 130 to aid in solder coverage for resulting solder region 150. The core member 142 is more rigid than normal solder, therefore it can counteract the package and motherboard warpage. In an alternate process flow, the solder dome 225 can be created before placing the electrical ball grid array (BGA), e.g., solder join regions 140 and 141. Circuit board assembly 205 can comprise a solder layer 240 that becomes part of solder region 150 during the SMT process that joins circuit board assembly 205 with partially manufactured semiconductor device assembly 201.

Although in FIGS. 2A-2B, one package substrate 125 and one circuit board 130 are depicted, it is possible to also create a stack comprising more than two levels where package substrates include land-side semiconductor devices 107. The land-side semiconductor devices 107 and solder domes 225 can be placed between any two levels of a stacked assembly comprising more than two levels.

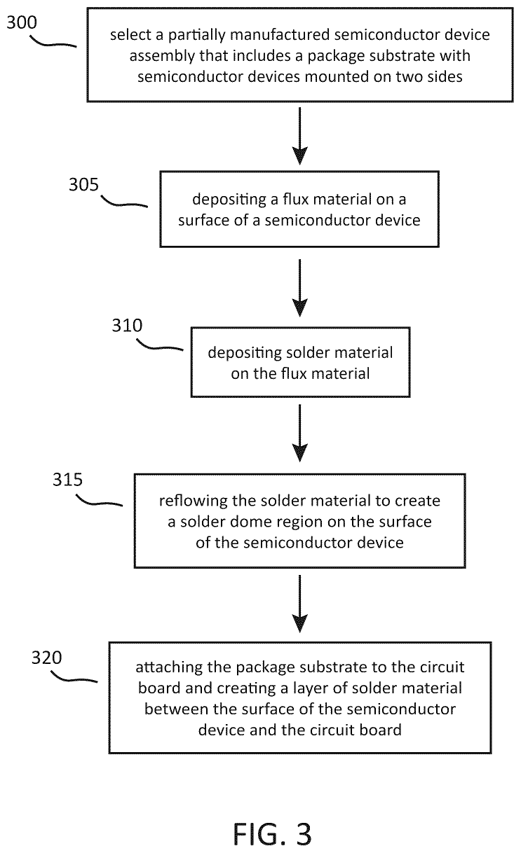

FIG. 3 provides a method for manufacturing a semiconductor device assembly.

The assembly can be any of those provided by FIGS. 1A-1C and 2A-2B and described herein. In FIG. 3, a partially manufactured semiconductor device assembly that includes a package substrate having semiconductor devices electrically coupled to two sides 300. A flux material is deposited on a surface of a semiconductor device that is coupled to the package substrate 305. A solder material is deposited on the flux material 310. The solder material can be in the form of preform or solder paste. The solder material is reflowed to create a solder dome region on the surface of semiconductor device 315. The solder dome region can cover more than 50%, more than 75%, more than 80%, more than 85%, more than 90%, more than 95%, or more than 98% of the surface of the semiconductor device. The package substrate is attached to a circuit board and the solder dome region is reflowed so that it becomes a layer of solder material between the semiconductor device and the circuit board 320. The circuit board can comprise a layer of solder material that mates up with the solder dome and reflows to form the layer of solder material.

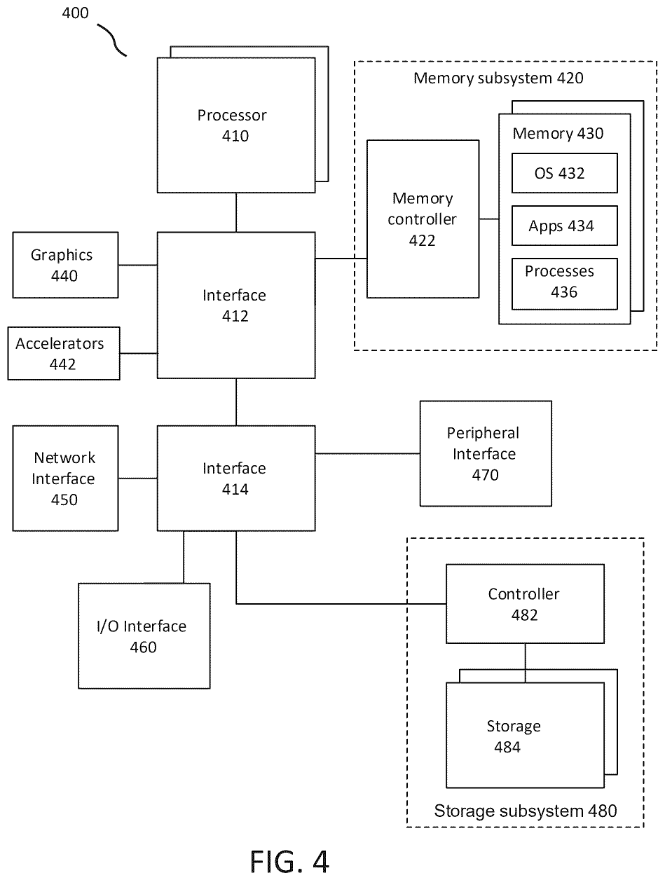

In FIGS. 1A-1C, 2A-2B, and 3, the semiconductor devices (or chips) can be any combination of microprocessors, CPUs (central processing units), GPUs (graphics processing units), processing cores, system on a chips, other processing hardware, a combination of processors or processing cores, programmable general-purpose or special-purpose microprocessors, accelerators, DSPs, I/O management, programmable controllers, ASICs, programmable logic devices (PLDs), HBM, power and voltage controllers, and/or other memory devices. These semiconductor chip packages can be heterogeneous packages that incorporate different types of chips into one package. The semiconductor chips can be any of the chips, for example, described herein with respect to FIG. 4. The semiconductor chip packages described herein generally can be part of various larger package structures and configurations and the foregoing examples are not meant to limit the types of assemblies that are possible.

FIG. 4 depicts an example computing system which can be used in conjunction with semiconductor processing equipment to perform the methods of FIGS. 2A-2B and 3. For example, instructions for operating semiconductor processing equipment, or for performing one or more aspects of the processes described in FIGS. 2A-2B and 3 can be stored and/or run on the computing system. In addition, the semiconductor devices described with respect to the computing system 400 can be part of assemblies according to FIGS. 1A-1C. A computing system 400 can include more, different, or fewer features than the ones described with respect to FIG. 4.

Computing system 400 includes processor 410, which provides processing, operation management, and execution of instructions for system 400. Processor 410 can include any type of microprocessor, CPU (central processing unit), GPU (graphics processing unit), processing core, or other processing hardware to provide processing for system 400, or a combination of processors or processing cores. Processor 410 controls the overall operation of system 400, and can be or include, one or more programmable general-purpose or special-purpose microprocessors, DSPs, programmable controllers, ASICs, programmable logic devices (PLDs), or the like, or a combination of such devices.

In one example, system 400 includes interface 412 coupled to processor 410, which can represent a higher speed interface or a high throughput interface for system components needing higher bandwidth connections, such as memory subsystem 420 or graphics interface components 440, and/or accelerators 442. Interface 412 represents an interface circuit, which can be a standalone component or integrated onto a processor die. Where present, graphics interface 440 interfaces to graphics components for providing a visual display to a user of system 400. In one example, the display can include a touchscreen display.

Accelerators 442 can be a fixed function or programmable offload engine that can be accessed or used by a processor 410. For example, an accelerator among accelerators 442 can provide data compression (DC) capability, cryptography services such as public key encryption (PKE), cipher, hash/authentication capabilities, decryption, or other capabilities or services. In some cases, accelerators 442 can be integrated into a CPU socket (e.g., a connector to a motherboard (or circuit board, printed circuit board, mainboard, system board, or logic board) that includes a CPU and provides an electrical interface with the CPU). For example, accelerators 442 can include a single or multi-core processor, graphics processing unit, logical execution unit single or multi-level cache, functional units usable to independently execute programs or threads, application specific integrated circuits (ASICs), neural network processors (NNPs), programmable control logic, and programmable processing elements such as field programmable gate arrays (FPGAs) or programmable logic devices (PLDs). Accelerators 442 can provide multiple neural networks, CPUs, processor cores, general purpose graphics processing units, or graphics processing units can be made available for use by artificial intelligence (AI) or machine learning (ML) models.

Memory subsystem 420 represents the main memory of system 400 and provides storage for code to be executed by processor 410, or data values to be used in executing a routine. Memory subsystem 420 can include one or more memory devices 430 such as read-only memory (ROM), flash memory, one or more varieties of random access memory (RAM) such as static RAM (SRAM), dynamic RAM (DRAM), synchronous DRAM (SDRAM) and/or or other memory devices, or a combination of such devices. Memory 430 stores and hosts, among other things, operating system (OS) 432 that provides a software platform for execution of instructions in system 400, and stores and hosts applications 434 and processes 436. In one example, memory subsystem 420 includes memory controller 422, which is a memory controller to generate and issue commands to memory 430. The memory controller 422 can be a physical part of processor 410 or a physical part of interface 412. For example, memory controller 422 can be an integrated memory controller, integrated onto a circuit within processor 410.

System 400 can also optionally include one or more buses or bus systems between devices, such memory buses, graphics buses, and/or interface buses. Buses or other signal lines can communicatively or electrically couple components together, or both communicatively and electrically couple the components. Buses can include physical communication lines, point-to-point connections, bridges, adapters, controllers, or other circuitry or a combination. Buses can include, for example, one or more of a system bus, a peripheral component interface (PCI) or PCI express (PCIe) bus, a Hyper Transport or industry standard architecture (ISA) bus, a small computer system interface (SCSI) bus, a universal serial bus (USB), or a Firewire bus.

In one example, system 400 includes interface 414, which can be coupled to interface 412. In one example, interface 414 represents an interface circuit, which can include standalone components and integrated circuitry. In one example, user interface components or peripheral components, or both, couple to interface 414. Network interface 450 provides system 400 the ability to communicate with remote devices (e.g., servers or other computing devices) over one or more networks. Network interface 450 can include an Ethernet adapter, wireless interconnection components, cellular network interconnection components, USB, or other wired or wireless standards-based or proprietary interfaces. Network interface 450 can transmit data to a device that is in the same data center or rack or a remote device, which can include sending data stored in memory.

Some examples of network interface 450 are part of an infrastructure processing unit (IPU) or data processing unit (DPU), or used by an IPU or DPU. An xPU can refer at least to an IPU, DPU, GPU, GPGPU (general purpose computing on graphics processing units), or other processing units (e.g., accelerator devices). An IPU or DPU can include a network interface with one or more programmable pipelines or fixed function processors to perform offload of operations that can have been performed by a CPU. The IPU or DPU can include one or more memory devices.

In one example, system 400 includes one or more input/output (I/O) interface(s) 460. I/O interface 460 can include one or more interface components through which a user interacts with system 400 (e.g., audio, alphanumeric, tactile/touch, or other interfacing). Peripheral interface 470 can include additional types of hardware interfaces, such as, for example, interfaces to semiconductor fabrication equipment and/or electrostatic charge management devices.

In one example, system 400 includes storage subsystem 480. Storage subsystem 480 includes storage device(s) 484, which can be or include any conventional medium for storing data in a nonvolatile manner, such as one or more magnetic, solid state, and/or optical based disks. Storage 484 can be generically considered to be a “memory,” although memory 430 is typically the executing or operating memory to provide instructions to processor 410. Whereas storage 484 is nonvolatile, memory 430 can include volatile memory (e.g., the value or state of the data is indeterminate if power is interrupted to system 400). In one example, storage subsystem 480 includes controller 482 to interface with storage 484. In one example controller 482 is a physical part of interface 412 or processor 410 or can include circuits or logic in both processor 410 and interface 414.

A power source (not depicted) provides power to the components of system 400. More specifically, power source typically interfaces to one or multiple power supplies in system 400 to provide power to the components of system 400.

Examples of systems may be implemented in various types of computing, smart phones, tablets, personal computers, and networking equipment, such as switches, routers, racks, and blade servers such as those employed in a data center and/or server farm environment.

An assembly can comprise: a package substrate wherein the package substrate comprises a first side and a second side and the first side is opposite the second side, wherein the first side comprises a first semiconductor device and the second side comprises a second semiconductor device, wherein the second semiconductor device is electrically coupled to the package substrate through an interconnect region, and wherein the second semiconductor device comprises a surface; and a layer of solder material on the surface of the second semiconductor device wherein the layer of solder material covers at least 80% of the surface of the second semiconductor device. The surface of the second semiconductor device can comprise a backside metallization region and the backside metallization region can be between the second semiconductor device and the layer of solder material. The assembly can additionally comprise a heat spreader wherein the heat spreader is thermally coupled to the first semiconductor device. The assembly can additionally comprise solder regions wherein the solder regions are capable of electrically coupling the package substrate to a circuit board. The assembly can additionally comprise solder regions wherein the solder regions are capable of electrically coupling the package substrate to a circuit board, wherein the solder regions comprise a core, and wherein the core is comprised of a material that is less deformable than a solder material in the solder regions. The layer of solder material can comprise a mixture of tin and bismuth, a mixture of tin, silver, and copper, a mixture of indium and bismuth, a mixture of indium and tin, or a mixture of indium, tin, and bismuth. The layer of solder material can comprise tin, bismuth, silver, lead, copper, indium, or a mixture thereof.

An assembly can comprise: a package substrate wherein the package substrate comprises a first side and a second side and the first side is opposite the second side, wherein the first side comprises a first semiconductor device and the second side comprises a second semiconductor device, wherein the second semiconductor device is electrically coupled to the package substrate through an interconnect region, and wherein the second semiconductor device comprises a surface; a layer of solder material on the surface of the second semiconductor device; and a circuit board wherein the layer of solder material is between the circuit board and the second semiconductor device and wherein the layer of solder material is thermally coupled to the circuit board. The surface of the second semiconductor device can comprise a backside metallization region and the backside metallization region is between the second semiconductor device and the layer of solder material. The circuit board can comprise a heat sink wherein the heat sink is thermally coupled to the second semiconductor device. The assembly can additionally comprise a heat spreader wherein the heat spreader is thermally coupled to the first semiconductor device. The assembly can additionally comprise solder regions wherein the solder regions are capable of electrically coupling the package substrate to the circuit board, wherein the solder regions comprise a core, and wherein the core is comprised of a material that is less deformable than a solder material in the solder regions. The layer of solder material can comprise a mixture of tin and bismuth, a mixture of tin, silver, and copper, a mixture of indium and bismuth, or a mixture of indium, tin, and bismuth. The layer of solder material can comprise tin, bismuth, silver, lead, indium, copper, or a mixture thereof.

A method can comprise: depositing a flux material on a surface of a semiconductor device wherein the surface of the semiconductor devices comprises a metal and wherein the semiconductor device is electrically coupled to a package substrate; depositing solder material on the flux material; reflowing the solder material to form a dome of solder material on the surface of the semiconductor device; and attaching the package substrate to a circuit board wherein attaching the package substrate comprises reflowing solder material and forming a layer of solder material between the surface of the semiconductor device and the circuit board. The method can additionally comprise removing a flux residue layer. The dome of solder material can cover at least 80% of the surface of the semiconductor device. The circuit board can comprise a layer of solder material. The package substrate can comprise solder regions wherein the solder regions are capable of electrically coupling the package substrate to the circuit board, wherein the solder regions comprise a core, and wherein the core is comprised of a material that is less deformable that a solder material in the solder regions. The layer of solder material can comprise tin, bismuth, silver, lead, indium, copper, or a mixture thereof.

Besides what is described herein, various modifications can be made to what is disclosed and implementations without departing from their scope. Therefore, the illustrations and examples herein should be construed in an illustrative, and not a restrictive sense.

What is claimed is:

1. An assembly comprising:
a package substrate wherein the package substrate comprises a first side and a second side and the first side is opposite the second side, wherein the first side comprises a first semiconductor device and the second side comprises a second semiconductor device, wherein the second semiconductor device is electrically coupled to the package substrate through an interconnect region, and wherein the second semiconductor device comprises a surface; and
a layer of solder material on the surface of the second semiconductor device wherein the layer of solder material covers at least 80% of the surface of the second semiconductor device.

2. The assembly of claim 1, wherein the surface of the second semiconductor device comprises a backside metallization region and the backside metallization region is between the second semiconductor device and the layer of solder material.

3. The assembly of claim 1 additionally comprising a heat spreader wherein the heat spreader is thermally coupled to the first semiconductor device.

4. The assembly of claim 1 additionally comprising solder regions wherein the solder regions are capable of electrically coupling the package substrate to a circuit board.

5. The assembly of claim 1 additionally comprising solder regions wherein the solder regions are capable of electrically coupling the package substrate to a circuit board, wherein the solder regions comprise a core, and wherein the core is comprised of a material that is less deformable than a solder material in the solder regions.

6. The assembly of claim 1 wherein the layer of solder material comprises a mixture of tin and bismuth, a mixture of tin, silver, and copper, a mixture of indium and bismuth, a mixture of indium and tin, or a mixture of indium, tin, and bismuth.

7. The assembly of claim 1 wherein the layer of solder material comprises tin, bismuth, silver, lead, copper, indium, or a mixture thereof.

8. An assembly comprising:
a package substrate wherein the package substrate comprises a first side and a second side and the first side is opposite the second side, wherein the first side comprises a first semiconductor device and the second side comprises a second semiconductor device, wherein the second semiconductor device is electrically coupled to the package substrate through an interconnect region, and wherein the second semiconductor device comprises a surface;
a layer of solder material on the surface of the second semiconductor device; and
a circuit board wherein the layer of solder material is between the circuit board and the second semiconductor device and wherein the layer of solder material is thermally coupled to the circuit board.

9. The assembly of claim 8 wherein the surface of the second semiconductor device comprises a backside metallization region and the backside metallization region is between the second semiconductor device and the layer of solder material.

10. The assembly of claim 8 wherein the circuit board comprises a heat sink wherein the heat sink is thermally coupled to the second semiconductor device.

11. The assembly of claim 8 additionally comprising a heat spreader wherein the heat spreader is thermally coupled to the first semiconductor device.

12. The assembly of claim 8 additionally comprising solder regions wherein the solder regions are capable of electrically coupling the package substrate to the circuit board, wherein the solder regions comprise a core, and wherein the core is comprised of a material that is less deformable than a solder material in the solder regions.

13. The assembly of claim 8 wherein the layer of solder material comprises a mixture of tin and bismuth, a mixture of tin, silver, and copper, a mixture of indium and bismuth, or a mixture of indium, tin, and bismuth.

14. The assembly of claim 8 wherein the layer of solder material comprises tin, bismuth, silver, lead, indium, copper, or a mixture thereof.

15. A method comprising:
depositing a flux material on a surface of a semiconductor device wherein the surface of the semiconductor devices comprises a metal and wherein the semiconductor device is electrically coupled to a package substrate;
depositing solder material on the flux material;
reflowing the solder material to form a dome of solder material on the surface of the semiconductor device; and
attaching the package substrate to a circuit board wherein attaching the package substrate comprises reflowing solder material and forming a layer of solder material between the surface of the semiconductor device and the circuit board.

16. The method of claim 15 wherein the method additionally comprises removing a flux residue layer.

17. The method of claim 15 wherein the dome of solder material covers at least 80% of the surface of the semiconductor device.

18. The method of claim 15 wherein the circuit board comprises a layer of solder material.

19. The method of claim 15 wherein the package substrate comprises solder regions wherein the solder regions are capable of electrically coupling the package substrate to the circuit board, wherein the solder regions comprise a core, and wherein the core is comprised of a material that is less deformable that a solder material in the solder regions.

20. The method of claim 15 wherein the layer of solder material comprises tin, bismuth, silver, indium, lead, copper, or a mixture thereof.
